(19) United States
(12) Patent Application Publication
(10) Pub. No.: US 2024/0080009 A1
(43) Pub. Date: Mar. 7, 2024

(54) PIEZOELECTRIC BULK WAVE DEVICE

(71) Applicant: Murata Manufacturing Co., Ltd., Nagaokakyo-shi (JP)

(72) Inventors: Akihiro IYAMA, Nagaokakyo-shi (JP); Yuta ISHII, Nagaokakyo-shi (JP)

(21) Appl. No.: 18/507,393

(22) Filed: Nov. 13, 2023

Related U.S. Application Data
(63) Continuation of application No. PCT/JP2022/018748, filed on Apr. 25, 2022.
(60) Provisional application No. 63/188,057, filed on May 13, 2021.

(51) Int. Cl. H03H 9/02; H03H 9/13; H03H 9/17

(52) U.S. Cl. CPC H03H 9/0211; H03H 9/02031; H03H 9/02228; H03H 9/132; H03H 9/173; H03H 9/175; H03H 9/176

(57) ABSTRACT

A piezoelectric bulk wave device includes a piezoelectric substrate including a support including a silicon substrate and a piezoelectric layer on the support, first and second wire electrodes on the piezoelectric substrate, and a functional electrode on the piezoelectric layer, connected to at least one of the first and second wire electrodes, and including multiple electrodes. At least two of the first and second wire electrodes, and the multiple electrodes include first and second electrode films connected to different potentials. A plane orientation of the silicon substrate is (111), and ψ in Euler angles (ϕ, θ, ψ) of the silicon substrate is an angle within a range of about 10°+120°×n≤ψ≤about 50°+120°×n or about 70°+120°×n≤ψ≤about 110°+120°×n, where n is any integer.

### CROSS REFERENCE TO RELATED APPLICATIONS

This application claims the benefit of priority to Provisional Application No. 63/188,057 filed on May 13, 2021 and is a Continuation Application of PCT Application No. PCT/JP2022/018748 filed on Apr. 25, 2022. The entire contents of each application are hereby incorporated herein by reference.

### BACKGROUND OF THE INVENTION

### 1. Field of the Invention

The present invention relates to a piezoelectric bulk wave device.

### 2. Description of the Related Art

Conventionally, acoustic wave devices such as piezoelectric bulk wave devices have been widely used in filters for mobile phones and the like. In recent years, a piezoelectric bulk wave device using bulk waves in a thickness shear mode has been proposed, as described in U.S. Pat. No. 10,491,192. In this piezoelectric bulk wave device, a piezoelectric layer is provided on a support. Paired electrodes are provided on the piezoelectric layer. The paired electrodes face each other on the piezoelectric layer and are connected to different potentials. By applying an AC voltage between the paired electrodes, bulk waves in the thickness shear mode are excited.

Japanese Unexamined Patent Application Publication No. 2011-182096 discloses an example of a ladder filter. In the ladder filter, multiple acoustic wave devices are connected by multiple wires. The multiple wires include a wire connected to a hot potential and a wire connected to a ground potential. The wire connected to the hot potential and the wire connected to the ground potential face each other.

As an acoustic wave device used in a ladder filter, a piezoelectric bulk wave device as described in U.S. Pat. No. 10,491,192 may be used. However, in piezoelectric bulk wave devices, unwanted bulk waves may be excited. The unwanted bulk waves propagate in a thickness direction of the piezoelectric layer. Therefore, the unwanted bulk waves may be reflected in the support. When the wires connected to different potentials face each other as in Japanese Unexamined Patent Application Publication No. 2011-182096, unwanted bulk wave signals may be extracted by one of the wires. Alternatively, the unwanted bulk wave signals may be extracted by one of busbars facing each other. In these cases, ripples may occur in frequency characteristics of the piezoelectric bulk wave device.

### SUMMARY OF THE INVENTION

Preferred embodiments of the present invention provide piezoelectric bulk wave devices that are each able to reduce or prevent ripples in frequency characteristics.

A piezoelectric bulk wave device according to a preferred embodiment of the present invention includes a piezoelectric substrate including a support including a silicon substrate and a piezoelectric layer on the support, a first wire electrode and a second wire electrode on the piezoelectric substrate, and a functional electrode on the piezoelectric layer, connected to at least one of the first wire electrode and the second wire electrode, and including a plurality of electrodes, in which at least two of the first wire electrode, the second wire electrode, and the plurality of electrodes of the functional electrode are a first electrode film and a second electrode film connected to different potentials, and a plane orientation of the silicon substrate is (111), and ψ in Euler angles (φ, θ, ψ) of the silicon substrate is an angle within a range of about 10°+120°×n≤ψ≤about 50°+120°×n or about 70°+120°×n≤ψ≤about 110°+120°×n, where n is any integer.

According to preferred embodiments of the present invention, piezoelectric bulk wave devices that are each able to reduce or prevent ripples in frequency characteristics are provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic elevational sectional view of a piezoelectric bulk wave device according to a first preferred embodiment of the present invention.

FIG. 2 is a schematic view for describing a definition of crystal axes of silicon.

FIG. 3 is a schematic view illustrating a (111) plane of silicon.

FIG. 4 is a view of the crystal axes of the (111) plane of silicon viewed from an XY plane in the first preferred embodiment of the present invention.

FIG. 5 is a schematic view illustrating a (100) plane of silicon.

FIG. 6 is a graph showing reflection characteristics of the first preferred embodiment of the present invention and a first comparative example.

FIG. 7 is a schematic elevational sectional view illustrating an example in which unwanted bulk waves propagate in the first comparative example.

FIG. 8 is a graph showing a relationship between ψ in Euler angles of a silicon substrate having a plane orientation (111) and ΔS11.

FIG. 9 is a graph showing reflection characteristics when ψ in the Euler angles of the silicon substrate having a plane orientation (111) is about 40° and about 60°.

FIG. 10 is a schematic plan view illustrating an electrode structure of a first IDT (interdigital transducer) electrode according to the first preferred embodiment of the present invention.

FIG. 11A is a schematic perspective view illustrating an appearance of a piezoelectric bulk wave device that uses bulk waves in a thickness shear mode, and FIG. 11B is a plan view illustrating an electrode structure on a piezoelectric layer.

FIG. 12 is a sectional view of a portion taken along line A-A in FIG. 11A.

FIG. 13A is a schematic elevational sectional view for explaining Lamb waves propagating through a piezoelectric film of a piezoelectric bulk wave device, and FIG. 13B is a schematic elevational sectional view for explaining bulk waves in the thickness shear mode propagating through a piezoelectric film in a piezoelectric bulk wave device.

FIG. 14 is a diagram illustrating an amplitude direction of bulk waves in the thickness shear mode.

FIG. 15 is a graph showing resonance characteristics of a piezoelectric bulk wave device that uses bulk waves in the thickness shear mode.

FIG. 16 is a graph showing a relationship between d/p and the fractional bandwidth as a resonator, where p is a center-to-center distance between adjacent electrodes and d is a thickness of a piezoelectric layer.

FIG. 17 is a plan view of a piezoelectric bulk wave device that uses bulk waves in the thickness shear mode.

FIG. 18 is a graph showing resonance characteristics of a piezoelectric bulk wave device as a reference example in which spurious emission appears.

FIG. 19 is a graph showing a relationship between the fractional bandwidth and the amount of phase rotation of impedance of spurious emission normalized by about 180 degrees as an amount of the spurious emission.

FIG. 20 is a graph showing a relationship between d/2p and the metallization ratio MR.

FIG. 21 is a diagram showing a map of fractional bandwidths for Euler angles (0°, θ, ψ) of LiNbO₃ when d/p is brought as close to 0 as possible.

FIG. 22 is an elevational sectional view of a piezoelectric bulk wave device having an acoustic multilayer film.

### DETAILED DESCRIPTION OF THE PREFERRED EMBODIMENTS

Hereinafter, preferred embodiments of the present invention will be described with reference to the drawings to clarify the present invention.

The preferred embodiments described in this specification are merely examples, and partial replacement or combination of structures and configurations is possible between different preferred embodiments.

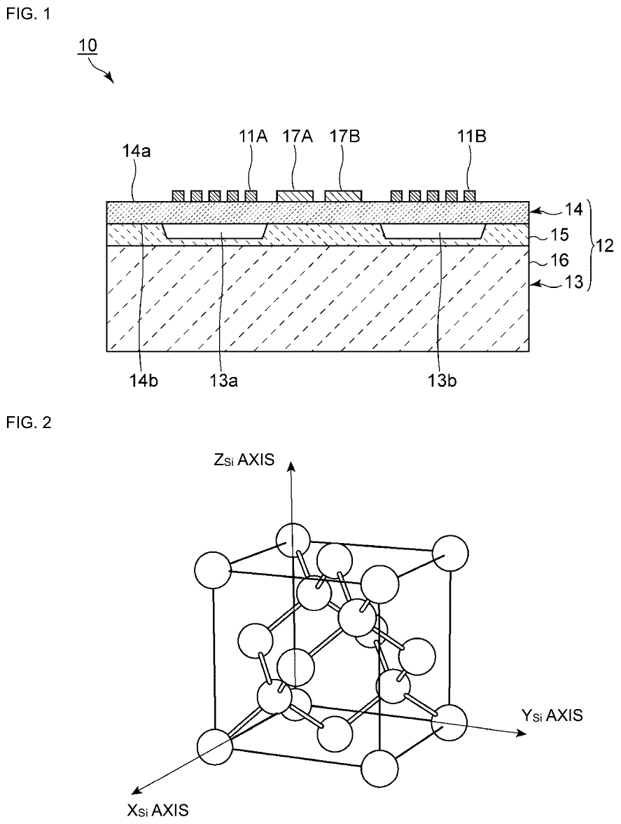

FIG. 1 is a schematic elevational sectional view of a piezoelectric bulk wave device according to a first preferred embodiment of the present invention.

As illustrated in FIG. 1, a piezoelectric bulk wave device 10 includes a piezoelectric substrate 12, and a first IDT electrode 11A and a second IDT electrode 11B as functional electrodes. The piezoelectric substrate 12 includes a support 13 and a piezoelectric layer 14. In the present preferred embodiment, the support 13 includes a silicon substrate 16 and an insulating layer 15. The insulating layer 15 is provided on the silicon substrate 16. The piezoelectric layer 14 is provided on the insulating layer 15. However, the support 13 may include only the silicon substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on a support 13 side.

As a material of the insulating layer 15, an appropriate dielectric such as, for example, silicon oxide or tantalum pentoxide can be used. As a material of the piezoelectric layer 14, for example, lithium niobate, lithium tantalate, zinc oxide, aluminum nitride, quartz crystal, lead zirconate titanate (PZT), or the like can be used. The piezoelectric layer 14 is preferably, for example, a lithium tantalate layer such as a LiTaO₃ layer, or a lithium niobate layer such as a LiNbO₃ layer.

The support 13 includes a cavity 13a and a cavity 13b. To be more specific, the insulating layer 15 includes multiple recesses. The piezoelectric layer 14 is provided on the insulating layer 15 so as to close the recesses. Thus, the cavity 13a and the cavity 13b are provided. The cavity 13a and the cavity 13b may be provided only in the insulating layer 15, or may be provided in both the silicon substrate 16 and the insulating layer 15. The cavity 13a and the cavity 13b of the present preferred embodiment are hollow portions. However, the cavity 13a and the cavity 13b may be through holes provided in the support 13.

The first IDT electrode 11A and the second IDT electrode 11B are provided on the first main surface 14a of the piezoelectric layer 14. Thus, two acoustic wave resonators are provided. The piezoelectric bulk wave device 10 only needs to include at least one acoustic wave resonator. The piezoelectric bulk wave device 10 can be used, for example, as a portion of a filter device. However, the number of acoustic wave resonators in the piezoelectric bulk wave device 10 may be three or more, or the piezoelectric bulk wave device 10 itself may be a filter device.

In plan view, at least portion of the first IDT electrode 11A overlaps the cavity 13a. In plan view, at least portion of the second IDT electrode 11B overlaps the cavity 13b. The support 13 only needs to be provided with at least one cavity. To be more specific, the insulating layer 15 only needs to be provided with at least one cavity. For example, the first IDT electrode 11A and the second IDT electrode 11B may overlap the same cavity in plan view. In this specification, “in plan view” means viewed from a direction corresponding to the upper side in FIG. 1. In FIG. 1, for example, of the silicon substrate 16 and the piezoelectric layer 14, the piezoelectric layer 14 is on the upper side.

Each of the first IDT electrode 11A and the second IDT electrode 11B includes a pair of busbars and multiple electrode fingers. In the present preferred embodiment, the multiple electrode fingers correspond to electrodes. The multiple electrode fingers of the first IDT electrode 11A face each other on the first main surface 14a. The same applies to the second IDT electrode 11B. When a direction in which adjacent electrode fingers face each other is referred to as an electrode finger facing direction and a direction in which the multiple electrode fingers extend is referred to as an electrode finger extending direction, the electrode finger facing direction and the electrode finger extending direction are orthogonal or substantially orthogonal in the present preferred embodiment. In each of the first IDT electrode 11A and the second IDT electrode 11B, the pair of busbars are connected to different potentials.

By applying an AC voltage to the first IDT electrode 11A, acoustic waves are excited. The same applies to the second IDT electrode 11B. In the present preferred embodiment, each acoustic wave resonator is structured to generate bulk waves in the thickness shear mode, such as a first order thickness shear mode, for example. The cavity 13a and the cavity 13b of the support 13 correspond to acoustic reflectors. The acoustic reflector can effectively confine acoustic waves to the piezoelectric layer 14 side. An acoustic multilayer film, which will be described later, may be provided as the acoustic reflector.

As illustrated in FIG. 1, a first wire electrode 17A and a second wire electrode 17B are provided on the first main surface 14a of the piezoelectric layer 14. The first wire electrode 17A and the second wire electrode 17B face each other on the first main surface 14a. The first wire electrode 17A is electrically connected to the first IDT electrode 11A. The second wire electrode 17B is connected to a potential different from the potential to which the first wire electrode 17A is connected. For example, the first wire electrode 17A may be connected to one busbar of the first IDT electrode 11A, and the second wire electrode 17B may be connected to the other busbar of the first IDT electrode 11A. Alternatively, the second wire electrode 17B may be connected to an element other than the first IDT electrode 11A. In the present preferred embodiment, the first wire electrode 17A corresponds to a first electrode film in the present invention. The second wire electrode 17B corresponds to a second electrode film in the present invention.

The first wire electrode 17A and the second wire electrode 17B are located between the first IDT electrode 11A and the second IDT electrode 11B. However, a positional relationship between the first wire electrode 17A, the second wire electrode 17B, the first IDT electrode 11A, and the second IDT electrode 11B is not limited to the above.

The present preferred embodiment is characterized by having the following configurations 1) to 3). 1) The first wire electrode 17A and the second wire electrode 17B are the first electrode film and the second electrode film connected to different potentials. 2) A plane orientation of the silicon substrate 16 is (111). 3) ψ4 in Euler angles (φ, θ, ψ) of the silicon substrate 16 is an angle within a range of about 10°+120°×n≤ψ≤about 50°+120°×n or about 70°+120°×n≤ψ≤about 110°+120°×n, where n is any integer. Thus, the influence of unwanted bulk waves on frequency characteristics can be reduced or prevented, so as to reduce or prevent ripples in the frequency characteristics. Details of this advantageous effect will be described below together with definitions of crystal axes, plane orientations, and the like.

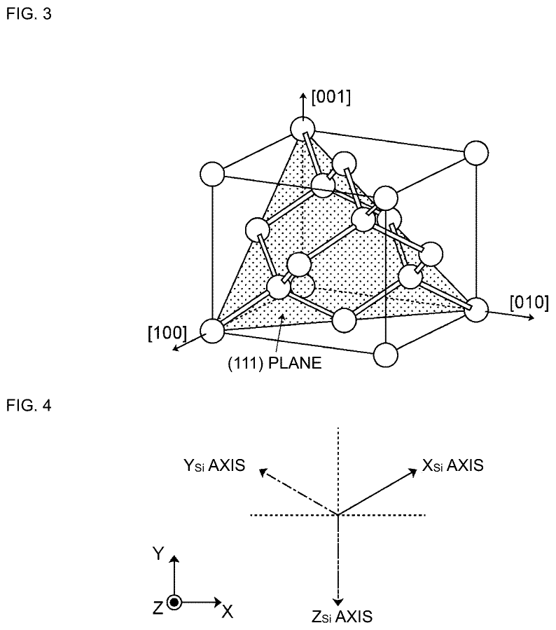

FIG. 2 is a schematic view for describing the definition of the crystal axes of silicon. FIG. 3 is a schematic view illustrating a (111) plane of silicon. FIG. 4 is a view of the crystal axes of the (111) plane of silicon viewed from an XY plane in the first preferred embodiment.

As illustrated in FIG. 2, a silicon single crystal has a diamond structure. In this specification, the crystal axes of silicon of the silicon substrate 16 are represented by [X_{Si}, Y_{Si}, Z_{Si}]. In silicon, the X_{Si} axis, the Y_{Si} axis, and the Z_{Si} axis are equivalent to each other due to symmetry of the crystal structure.

The plane orientation of the silicon substrate 16 in the first preferred embodiment is (111). “The plane orientation is (111)” indicates that a substrate or layer is cut along the (111) plane orthogonal or substantially orthogonal to crystal axes represented by Miller indices [111] in the crystal structure of silicon having a diamond structure. The (111) plane is a plane illustrated in FIGS. 3 and 4. However, the (111) plane includes other crystallographically equivalent planes. As illustrated in FIG. 4, a crystal structure has three-fold symmetry in the (111) plane, and about 120° rotation results in an equivalent crystal structure.

In the following, the advantageous effects of the present preferred embodiment will be described in detail by comparing the first preferred embodiment and a first comparative example. The first comparative example differs from the present preferred embodiment in that a plane orientation of the silicon substrate is (100). “The plane orientation is (100)” indicates that a substrate or layer is cut along the (100) plane orthogonal or substantially orthogonal to crystal axes represented by Miller

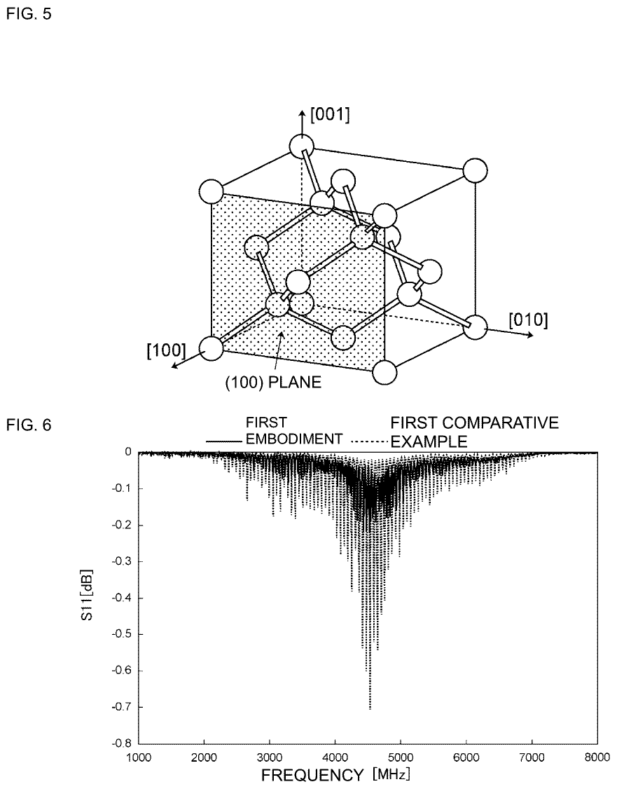

indices in the crystal structure of silicon having a diamond structure. A crystal structure has four-fold symmetry in the (100) plane, and about 90° rotation results in an equivalent crystal structure. The (100) plane is a plane illustrated in FIG. 5.

In the piezoelectric bulk wave devices of the first preferred embodiment and the first comparative example, frequency characteristics were compared by a finite element method (FEM) simulation. To be specific, reflection characteristics as the frequency characteristics between the first wire electrode and the second wire electrode were compared. In the FEM simulation, the Euler angles (φ, θ, ψ) of the silicon substrate in the first preferred embodiment were set to (about −45°, about 54.73561°, about 73°).

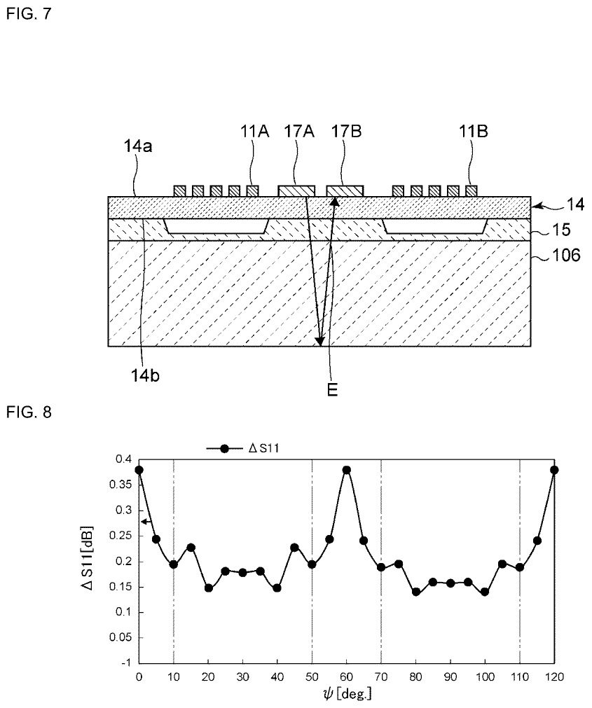

FIG. 6 is a graph showing the reflection characteristics of the first preferred embodiment and the first comparative example. The reflection characteristics shown in FIG. 6 are a relationship between S11 and the frequency. FIG. 7 is a schematic elevational sectional view illustrating an example in which unwanted bulk waves propagate in the first comparative example. An arrow E in FIG. 7 indicates part of the unwanted bulk waves.

As shown in FIG. 6, it can be seen that in the reflection characteristics of the first comparative example, ripples become large around about 2200 MHz to about 7000 MHz shown in FIG. 6. As illustrated in FIG. 7, in the first comparative example, for example, the unwanted bulk waves propagated from the first wire electrode 17A are reflected in the silicon substrate 106. Unwanted bulk wave signals are extracted by the second wire electrode 17B. Therefore, the ripples shown in FIG. 6 occur. On the other hand, it can be seen that the ripples are reduced or prevented in the reflection characteristics of the first preferred embodiment.

Here, the maximum value of S11 is max(S11), the minimum value of S11 is min(S11), and max(S11)−min(S11)=ΔS11. ΔS11 corresponds to a ripple size in the reflection characteristics. ΔS11 in the first preferred embodiment and ΔS11 in the first comparative example from about 4300 MHz to about 4700 MHz were compared. As a result, ΔS11 in the first preferred embodiment was about −73.2% of ΔS11 in the first comparative example. Thus, in the first preferred embodiment, ripples can be effectively reduced or prevented.

A reason for the large ripples in the first comparative example is that standing waves are easily generated in the silicon substrate. To be more specific, in a section of the silicon substrate in a direction parallel or substantially parallel to the electrode finger facing direction, a displacement distribution due to the bulk waves at, for example, about 4500 MHz has a substantially constant period in a thickness direction. On the other hand, in a section of the silicon substrate in a direction parallel or substantially parallel to the electrode finger extending direction, displacement due to the bulk waves at about 4500 MHz is less likely to occur. For these reasons, standing waves generated by the bulk waves occur in the thickness direction. Therefore, intensity of the unwanted bulk waves that reach the second wire electrode 17B increases, thus increasing the ripples in the frequency characteristics.

On the other hand, when the plane orientation of the silicon substrate 16 is (111) as in the first preferred embodiment illustrated in FIG. 1, standing waves are less likely to occur in the silicon substrate 16. To be more specific, in a section of the silicon substrate 16 in a direction parallel or substantially parallel to the electrode finger facing direction, displacement distribution due to the bulk waves at, for example, about 4500 MHz is complicated. The same applies to a section of the silicon substrate 16 in a direction parallel or substantially parallel to the electrode finger extending direction. For these reasons, standing waves generated by the bulk waves hardly occur. Therefore, intensity of the unwanted bulk waves that reach the second wire electrode 17B is low, thus reducing or preventing the ripples in the frequency characteristics.

Furthermore, in the first preferred embodiment, ψ in the Euler angles (φ, θ, ψ) of the silicon substrate 16 is an angle within the range of about 10°+120°×n≤ψ≤about 50°+about 120°×n or about 70°+120°×n≤ψ≤about 110°+120°×n. Note that n is any integer. Thus, the ripples in the frequency characteristics can be effectively reduced or prevented. This is shown below.

In a silicon substrate having a plane orientation (111), the ripple size and return loss due to unwanted bulk waves were evaluated by rotating the orientation in-plane. To be more specific, Euler angles (φ, θ, ψ) of the silicon substrate were set to (about −45°, about 54.73561°, ψ), and the orientation was rotated in-plane by changing ψ. Each time ϕ was changed, max(S11) and min(S11) were measured to calculate ΔS11. ΔS11 corresponds to the ripple size in the frequency characteristics.

FIG. 8 is a graph showing a relationship between ψ in the Euler angles of a silicon substrate having a plane orientation (111) and ΔS11.

As shown in FIG. 8, ΔS11 can be effectively reduced in ranges of about 10°≤ψ≤about 50° and about 70°≤ψ≤about 110°. Therefore, in the ranges of about 10°≤ψ≤about 50° and about 70°≤ψ≤about 110°, ripples in the frequency characteristics can be effectively reduced or prevented.

The crystal structure has three-fold symmetry in the (111) plane, and about 120° rotation results in an equivalent crystal structure. Therefore, about 10°≤ψ≤about 50° is equivalent to about 10°+120°×n≤ψ≤ about 50°+120°×n, where n is any integer. About 70°≤ψ≤about 110° is equivalent to about 70°+120°×n≤ψ≤ about 110°+120°×n. In the present preferred embodiment, ψ in the Euler angles (φ, θ, ψ) of the silicon substrate 16 is an angle within the range of about 10°+120°×n≤ψ≤about 50°+120°×n or about 70°+120°×n≤ψ≤ about 110°+120°×n. Therefore, ripples in the frequency characteristics can be effectively reduced or prevented.

As shown in FIG. 8, when ψ is around 40°, ΔS11 is particularly small. On the other hand, when ψ is around 60°, ΔS11 is relatively large. Here, the reflection characteristics when ψ is around 40° and when ψ is around 60° are shown.

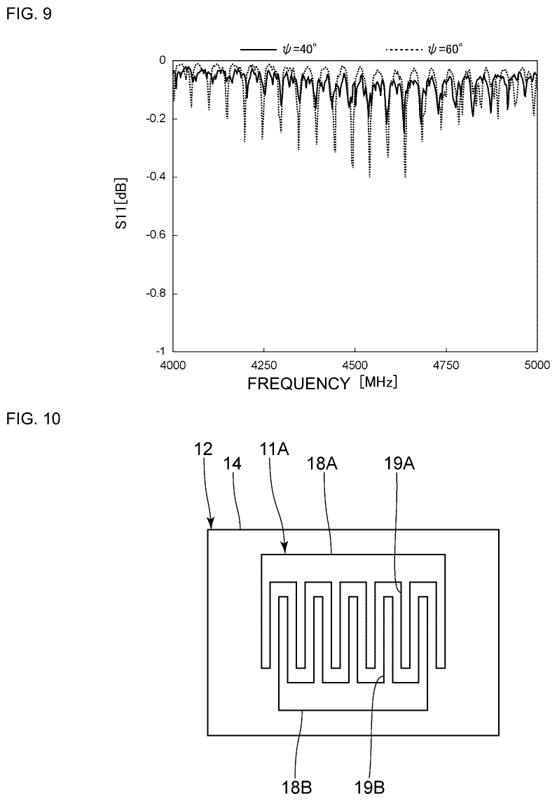

FIG. 9 is a graph showing the reflection characteristics when ψ in Euler angles of a silicon substrate having a plane orientation (111) is about 40° and about 60°.

It can be seen that ripples in the reflection characteristics as the frequency characteristics are reduced or prevented in the case of ψ is about 40° compared to the case of ψ is about 60°. Although not shown, ΔS11 when the plane orientation of the silicon substrate is (111) and ψ is about 60° is about −45% of ΔS11 when the plane orientation of the silicon substrate is (100) and ψ is about 0°. On the other hand, ΔS11 when the plane orientation of the silicon substrate is (111) and ψ is about 40° is about −78% of ΔS11 when the plane orientation of the silicon substrate is (100) and ψ is about 0°. Thus, when ψ is about 40°, ripples in the frequency characteristics can be effectively reduced or prevented.

In the first preferred embodiment illustrated in FIG. 1, the first electrode film is the first wire electrode 17A. The second electrode film is the second wire electrode 17B. In the piezoelectric bulk wave device 10, extraction of unwanted bulk wave signals by the first wire electrode 17A or the second wire electrode 17B is reduced or prevented. Propagation and extraction of unwanted bulk wave signals may also occur between the pair of busbars of one IDT electrode. An electrode structure of the first IDT electrode 11A in the present preferred embodiment will be described below.

FIG. 10 is a schematic plan view illustrating the electrode structure of the first IDT electrode according to the first preferred embodiment. In FIG. 10, wires and the like connected to the first IDT electrode 11A are omitted.

The first IDT electrode 11A includes a first busbar 18A, a second busbar 18B, multiple first electrode fingers 19A, and multiple second electrode fingers 19B. The first busbar 18A and the second busbar 18B face each other. One end of each of the multiple first electrode fingers 19A is connected to the first busbar 18A. One end of each of the multiple second electrode fingers 19B is connected to the second busbar 18B. The multiple first electrode fingers 19A and the multiple second electrode fingers 19B are interdigitated with each other. Similar to the first IDT electrode 11A, the second IDT electrode 11B illustrated in FIG. 1 also includes a pair of busbars and multiple electrode fingers. The first IDT electrode 11A and the second IDT electrode 11B may include a single layer metal film or a laminated metal film.

The first busbar 18A and the second busbar 18B are connected to different potentials. Therefore, as described above, propagation and extraction of unwanted bulk wave signals may also occur between the pair of busbars. Further, the first busbar 18A and the first electrode fingers 19A have the same potential. Similarly, the second busbar 18B and the second electrode fingers 19B have the same potential. Therefore, propagation and extraction of unwanted bulk wave signals may also occur between the first busbar 18A or the first electrode fingers 19A and the second busbar 18B or the second electrode fingers 19B.

However, in the first preferred embodiment, the silicon substrate 16 is configured as described above. Therefore, for example, also when the first electrode film is the first busbar 18A or the first electrode fingers 19A and the second electrode film is the second busbar 18B or the second electrode fingers 19B, influence of the unwanted bulk waves on the frequency characteristics can be reduce or prevent, thus reducing or preventing ripples in the frequency characteristics.

Here, the first busbar 18A and the second busbar 18B, or the multiple first electrode fingers 19A and the multiple second electrode fingers 19B correspond to at least one pair of electrodes of the functional electrode. Of the at least one pair of electrodes, for example, the first busbar 18A or the first electrode fingers 19A may correspond to the first electrode film, and the second busbar 18B or the second electrode fingers 19B may correspond to the second electrode film. That is, at least two of the first wire electrode 17A, the second wire electrode 17B, and the multiple electrodes of the functional electrode need only be the first electrode film and the second electrode film connected to different potentials.

As illustrated in FIG. 1, the first IDT electrode 11A and the second IDT electrode 11B of the piezoelectric bulk wave device 10 are provided on the first main surface 14a of the piezoelectric layer 14. The first IDT electrode 11A and the second IDT electrode 11B may be provided on the second main surface 14b of the piezoelectric layer 14. When the functional electrode is the IDT electrode, at least one pair of electrodes need only be provided on the same main surface of the piezoelectric layer 14.

In the following, the thickness shear mode will be described in detail. A piezoelectric bulk wave device is a type of acoustic wave device. Hereinafter, the piezoelectric bulk wave device may be referred to as the acoustic wave device. The following example includes a case where a substrate corresponding to the silicon substrate is a substrate made of a material different from that of the silicon substrate. This substrate will be described below as a support. Further, electrodes in the following example correspond to the electrode fingers.

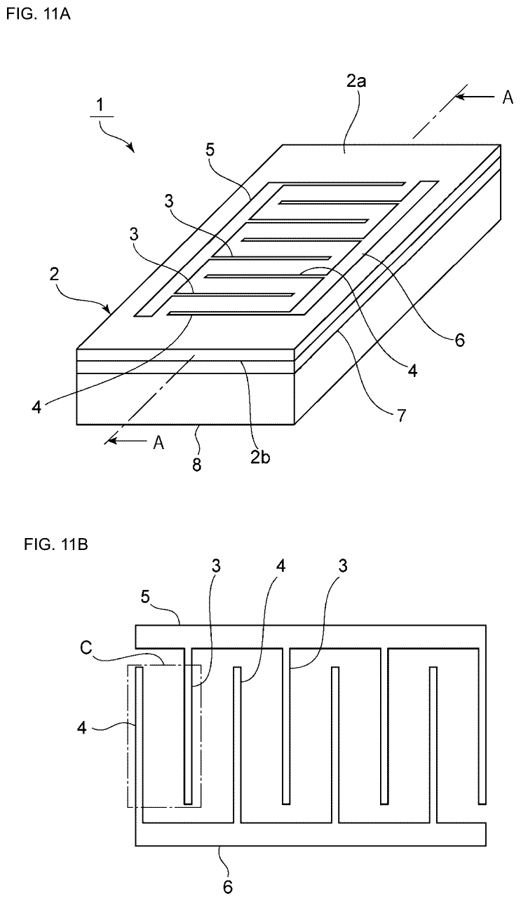

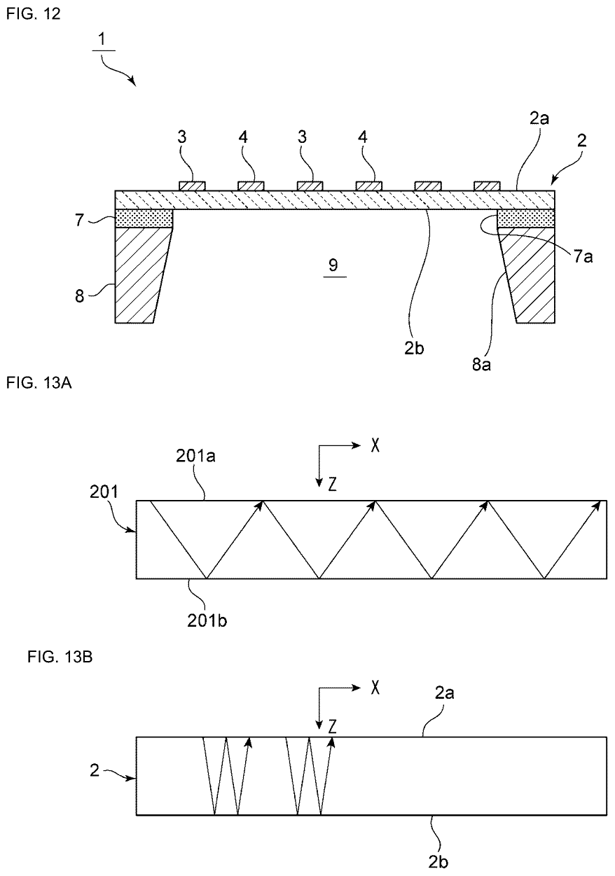

FIG. 11A is a schematic perspective view illustrating an appearance of an acoustic wave device that uses bulk waves in a thickness shear mode, FIG. 11B is a plan view illustrating an electrode structure on a piezoelectric layer, and FIG. 12 is a sectional view of a portion taken along line A-A in FIG. 11A.

An acoustic wave device 1 includes a piezoelectric layer 2 made of, for example, LiNbO₃. The piezoelectric layer 2 may be made of, for example, LiTaO₃. Cut-angles of LiNbO₃ and LiTaO₃ are Z-cut, but may be rotated Y-cut or X-cut. A thickness of the piezoelectric layer 2 is not particularly limited. In order to effectively excite the thickness shear mode, the thickness of the piezoelectric layer 2 is preferably, for example, about 40 nm or more and about 1000 nm or less, and more preferably about 50 nm or more and about 1000 nm or less. The piezoelectric layer 2 includes first and second main surfaces 2a and 2b facing each other. An electrode 3 and an electrode 4 are provided on the first main surface 2a. In FIGS. 11A and 11B, the multiple electrodes 3 are multiple first electrode fingers connected to a first busbar 5. The multiple electrodes 4 are multiple second electrode fingers connected to a second busbar 6. The multiple electrodes 3 and the multiple electrodes 4 are interdigitated with each other. The electrode 3 and the electrode 4 have a rectangular or substantially rectangular shape and have a length direction. The electrode 3 and the adjacent electrode 4 face each other in a direction orthogonal or substantially orthogonal to the length direction. The length direction of the electrodes 3 and 4 and the direction orthogonal or substantially orthogonal to the length direction of the electrodes 3 and 4 are both directions intersecting a thickness direction of the piezoelectric layer 2. Therefore, it can also be said that the electrode 3 and the adjacent electrode 4 face each other in the direction intersecting the thickness direction of the piezoelectric layer 2. Further, the length direction of the electrodes 3 and 4 may be replaced with the direction orthogonal or substantially orthogonal to the length direction of the electrodes 3 and 4 illustrated in FIGS. 11A and 11B. That is, in FIGS. 11A and 11B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 11A and 11B. Multiple pairs of the electrodes 3 and 4 are provided in the direction orthogonal or substantially orthogonal to the length direction of the electrodes 3 and 4, each pair having a structure in which the electrode 3 connected to one potential and the electrode 4 connected to another potential are adjacent to each other. Here, the expression “the electrode 3 and the electrode 4 are adjacent to each other” does not mean that the electrode 3 and the electrode 4 are arranged so as to be in direct contact with each other but means that the electrode 3 and the electrode 4 are arranged with a space interposed therebetween. Further, when the electrode 3 and the electrode 4 are adjacent to each other, no electrodes connected to a hot electrode or a ground electrode, including the other electrodes 3 and 4, are placed between the electrode 3 and the electrode 4. The number of pairs need not be integer pairs, but may be, for example, 1.5 pairs or 2.5 pairs. A center-to-center distance between the electrodes 3 and 4, that is, a pitch between the electrodes 3 and 4 is preferably in a range from, for example, about 1 μm to about 10 μm. In addition, widths of the electrodes 3 and 4, that is, dimensions of the electrodes 3 and 4 in a facing direction are preferably in a range from, for example, about 50 nm to about 1000 nm, and more preferably in a range from about 150 nm to about 1000 nm. The center-to-center distance between the electrodes 3 and 4 is a distance between the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

Since the acoustic wave device 1 uses a Z-cut piezoelectric layer, the direction orthogonal or substantially orthogonal to the length direction of the electrodes 3 and 4 is a direction orthogonal or substantially orthogonal to a polarization direction of the piezoelectric layer 2. The above does not apply when a piezoelectric material having different cut-angles is used as the piezoelectric layer 2. Here, “orthogonal” is not limited to strictly orthogonal, but may be substantially orthogonal (an angle between the direction orthogonal or substantially orthogonal to the length direction of the electrodes 3 and 4 and the polarization direction is within a range of about 90°±10°, for example).

A support 8 is laminated on a second main surface 2b side of the piezoelectric layer 2 with an insulating layer 7 interposed therebetween. The insulating layer 7 and the support 8 have frame shapes, and include through holes 7a and 8a, respectively, as illustrated in FIG. 12. Thus, a cavity 9 is provided. The cavity 9 is provided so as not to hinder vibration of the piezoelectric layer 2 in an excitation region C. Consequently, the support 8 is laminated on the second main surface 2b with the insulating layer 7 interposed therebetween, at a position not overlapping a portion where at least one pair of the electrodes 3 and 4 is provided. The insulating layer 7 does not necessarily have to be provided. Consequently, the support 8 can be laminated directly or indirectly on the second main surface 2b of the piezoelectric layer 2.

The insulating layer 7 is made of, for example, about silicon oxide. However, in place of silicon oxide, an appropriate insulating material such as, for example, silicon oxynitride or alumina may be used. The support 8 is made of, for example, Si. A plane orientation of a surface of Si on a piezoelectric layer 2 side may be (100), (110), or (111). Si of the support 8 preferably has a high resistivity of, for example, about 4 kΩcm or more. However, the support 8 can also be made using an appropriate insulating material or semiconductor material.

Examples of the material of the support 8 include piezoelectric materials such as aluminum oxide, lithium tantalate, lithium niobate, and quartz crystal; various ceramics such as alumina, magnesia, sapphire, silicon nitride, aluminum nitride, silicon carbide, zirconia, cordierite, mullite, steatite, and forsterite; dielectrics such as diamond and glass; and semiconductors such as gallium nitride.

The multiple electrodes 3 and 4 and the first and second busbars 5 and 6 are made of an appropriate metal or alloy such as, for example, Al or an AlCu alloy. In the present preferred embodiment, the electrodes 3 and 4 and the first and second busbars 5 and 6 include, for example, an Al film is laminated on a Ti film. An adhesion layer other than the Ti film may be used.

When driving, an AC voltage is applied between the multiple electrodes 3 and the multiple electrodes 4. To be more specific, the AC voltage is applied between the first busbar 5 and the second busbar 6. Thus, resonance characteristics can be obtained using bulk waves in the thickness shear mode excited in the piezoelectric layer 2. In the acoustic wave device 1, d/p is, for example, about 0.5 or less, where d is a thickness of the piezoelectric layer 2 and p is a center-to-center distance between any adjacent electrodes 3 and 4 among the multiple pairs of electrodes 3 and 4. Therefore, the bulk waves in the thickness shear mode are effectively excited, and good resonance characteristics can be obtained. More preferably, for example, d/p is about 0.24 or less, in which case even better resonance characteristics can be obtained.

Since the acoustic wave device 1 has the above-described configuration, even when the number of pairs of the electrodes 3 and 4 is reduced in order to achieve miniaturization, Q factor is hardly reduced. This is because a propagation loss is small even when the number of electrode fingers in reflectors on both sides is reduced. The number of the electrode fingers can be reduced because of the use of bulk waves in the thickness shear mode. A difference between Lamb waves used in an acoustic wave device and the bulk waves in the thickness shear mode will be described with reference to FIGS. 13A and 13B.

FIG. 13A is a schematic elevational sectional view for explaining Lamb waves propagating through a piezoelectric film of an acoustic wave device as described in Japanese Unexamined Patent Application Publication No. 2012-257019. Here, the waves propagate through a piezoelectric film 201 as indicated by arrows. Here, in the piezoelectric film 201, a first main surface 201a and a second main surface 201b face each other, and a thickness direction connecting the first main surface 201a and the second main surface 201b is a Z-direction. An X-direction is a direction in which electrode fingers of an IDT electrode are aligned. As illustrated in FIG. 13A, in the Lamb waves, the waves propagate in the X-direction as illustrated. Since the Lamb waves are plate waves, the piezoelectric film 201 vibrates as a whole, but since the waves propagate in the X-direction, reflectors are provided on both sides to obtain resonance characteristics. Therefore, a wave propagation loss occurs, and when miniaturization is attempted, that is, when the number of pairs of electrode fingers is reduced, the Q factor decreases.

On the other hand, as illustrated in FIG. 13B, in the acoustic wave device 1, a vibration displacement is in a thickness shear direction, so waves propagate in or substantially in a direction connecting the first main surface 2a and the second main surface 2b of the piezoelectric layer 2, that is, in the Z-direction, and resonate. That is, an X-direction component of the wave is significantly smaller than the Z-direction component of the wave. Since resonance characteristics are obtained by the propagation of the waves in the Z-direction, propagation loss hardly occurs even when the numbers of electrode fingers of the reflectors are reduced. Furthermore, even when the number of pairs of the electrodes 3 and 4 is reduced in order to promote miniaturization, the Q factor is less likely to decrease.

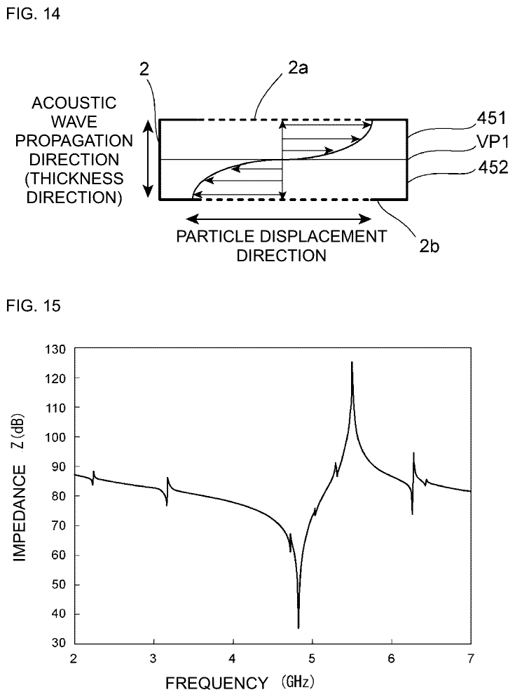

As illustrated in FIG. 14, an amplitude direction of the bulk waves in the thickness shear mode is opposite between a first region 451 included in the excitation region C of the piezoelectric layer 2 and a second region 452 included in the excitation region C. In FIG. 14, bulk waves are schematically illustrated when a voltage is applied between the electrode 3 and the electrode 4 such that the electrode 4 has a higher potential than the electrode 3. The first region 451 is a region of the excitation region C between the first main surface 2a and a virtual plane VP1 that is orthogonal or substantially orthogonal to the thickness direction of the piezoelectric layer 2 and bisects the piezoelectric layer 2. The second region 452 is a region of the excitation region C between the virtual plane VP1 and the second main surface 2b.

As described above, in the acoustic wave device 1, at least one pair of electrodes including the electrode 3 and the electrode 4 is disposed. However, since waves are not propagated in the X-direction, the number of pairs of electrodes of the electrodes 3 and 4 does not need to be multiple. That is, it is sufficient that at least one pair of electrodes is provided.

For example, the electrode 3 is an electrode connected to a hot potential, and the electrode 4 is an electrode connected to a ground potential. However, the electrode 3 may be connected to the ground potential and the electrode 4 may be connected to the hot potential. In the present preferred embodiment, as described above, each of the at least one pair of electrodes is an electrode connected to the hot potential or an electrode connected to the ground potential, and no floating electrode is provided.

FIG. 15 is a graph showing resonance characteristics of the acoustic wave device illustrated in FIG. 12. Design parameters of the acoustic wave device 1 having these resonance characteristics are as follows.

Piezoelectric layer 2: LiNbO₃ with Euler angles (0°, 0°,) 90°, thickness is about 400 nm.

When viewed in a direction orthogonal or substantially orthogonal to the length direction of the electrode 3 and the electrode 4, a length, of the region where the electrode 3 and the electrode 4 overlap, that is, of the excitation region C, is about 40 μm, the number of pairs of electrodes 3 and 4 is 21, a center-to-center distance between the electrodes is 3 μm, a width of the electrodes 3 and 4 is about 500 nm, and d/p is about 0.133.

Insulating layer 7: silicon oxide film with a thickness of about 1 μm.

Support 8: Si.

The length of the excitation region C is a dimension of the excitation region C along the length direction of the electrodes 3 and 4.

In the present preferred embodiment, inter-electrode distances of the electrode pairs of the electrodes 3 and 4 are all made equal or substantially equal in multiple pairs. That is, the electrodes 3 and the electrodes 4 are arranged at equal or substantially equal pitches.

As is clear from FIG. 15, good resonance characteristics with a fractional bandwidth of about 12.5% are obtained even though no reflectors are provided.

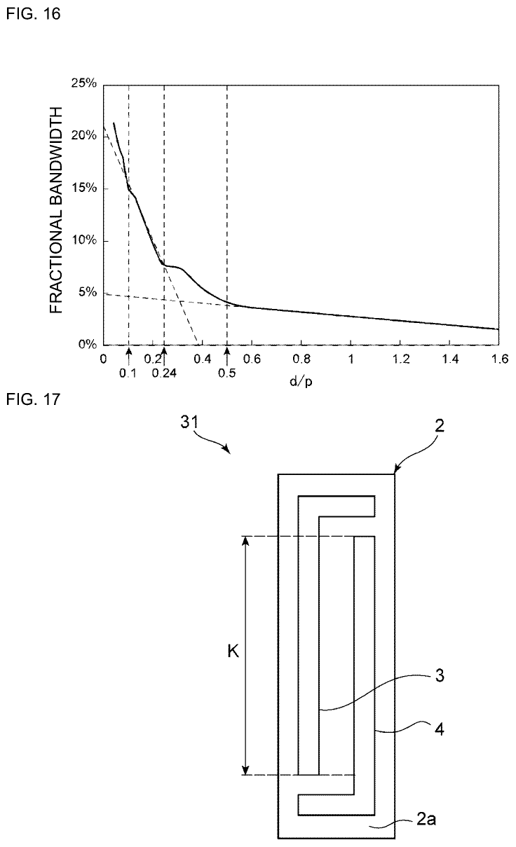

For example, d/p is about 0.5 or less and more preferably about 0.24 or less, as described above in the present preferred embodiment, where d is the thickness of the piezoelectric layer 2 and p is the center-to-center distance between the electrode 3 and the electrode 4. This will be described with reference to FIG. 16.

Multiple acoustic wave devices were obtained in the same or substantially the same manner as the acoustic wave device having the resonance characteristics shown in FIG. 15, except that d/p was changed. FIG. 16 is a graph showing a relationship between the d/p and the fractional bandwidth of the acoustic wave device as a resonator.

As is clear from FIG. 16, for example, when d/p is more than about 0.5, the fractional bandwidth is less than about 5% even when d/p is changed. On the other hand, for example, when d/p is about 0.5 or less, by changing d/p within this range, the fractional bandwidth can be set to about 5% or more, that is, a resonator having a high coupling coefficient can be configured. Further, for example, when d/p is about 0.24 or less, the fractional bandwidth can be increased to about 7% or more. In addition, when d/p is changed within this range, a resonator having an even wider fractional bandwidth can be obtained, thus achieving a resonator having an even higher coupling coefficient. Therefore, it can be seen that by setting d/p to about 0.5 or less, a resonator having a high coupling coefficient using the bulk waves in the thickness shear mode can be configured.

FIG. 17 is a plan view of an acoustic wave device using bulk waves in the thickness shear mode. In an acoustic wave device 31, a pair of electrodes including electrodes 3 and 4 is provided on a first main surface 2a of a piezoelectric layer 2. K in FIG. 17 is an intersecting width. As described above, in the acoustic wave device, the number of pairs of electrodes may be one. Even in this case, for example, when d/p is about 0.5 or less, the bulk waves in the thickness shear mode can be effectively excited.

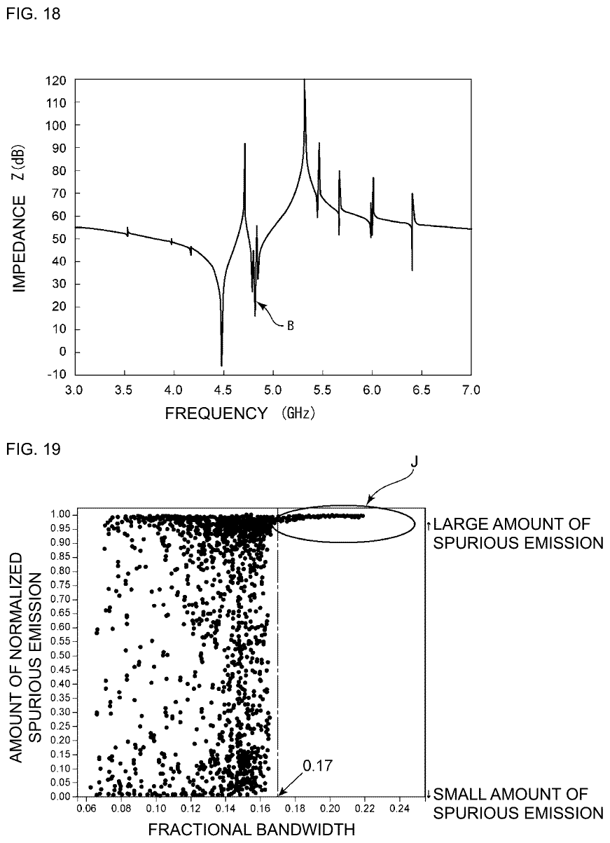

In the acoustic wave device 1, preferably, a metallization ratio MR of any adjacent electrodes 3 and 4 to the excitation region C, which is a region in which the adjacent electrodes 3 and 4 overlap when viewed in a facing direction of the adjacent electrodes 3 and 4 satisfies: MR≤about 1.75(d/p)+0.075. In this case, spurious emission can be effectively reduced or prevented. This will be described with reference to FIGS. 18 and 19. FIG. 18 is a reference graph showing an example of resonance characteristics of the acoustic wave device 1. A spurious emission indicated by an arrow B appears between a resonant frequency and an anti-resonant frequency. Note that d/p was about 0.08 and the Euler angles of LiNbO₃ were (0°, 0°, 90°). The metallization ratio MR was set to about 0.35.

The metallization ratio MR will be explained with reference to FIG. 11B. When attention is paid to a pair of the electrodes 3 and 4 in the electrode structure in FIG. 11B, it is assumed that only this pair of the electrodes 3 and 4 is provided. In this case, an area surrounded by an alternate long and short dash line is the excitation region C. The excitation region C is a region of the electrode 3 overlapping the electrode 4, a region of the electrode 4 overlapping the electrode 3, and a region between the electrode 3 and the electrode 4, where the electrode 3 and the electrode 4 overlap when the electrode 3 and the electrode 4 are viewed in a direction orthogonal or substantially orthogonal to the length direction of the electrodes 3 and 4, that is, in the facing direction. Areas of the electrodes 3 and 4 in the excitation region C to an area of the excitation region C is the metallization ratio MR. That is, the metallization ratio MR is a ratio of the area of a metallization portion to the area of the excitation region C.

When multiple pairs of electrodes are provided, a ratio of metallization portions included in an entire excitation region to the sum of areas of the excitation regions may be defined as MR.

FIG. 19 is a graph showing a relationship between the fractional bandwidth and a phase rotation amount of impedance of the spurious emission normalized by about 180 degrees as an amount of the spurious emission when a large number of acoustic wave resonators are configured according to the present preferred embodiment. The fractional bandwidths were adjusted by variously changing the thickness of the piezoelectric layer and the dimensions of the electrodes. Although FIG. 19 shows results when a piezoelectric layer made of Z-cut LiNbO₃ is used, the same tendency occurs even when piezoelectric layers having other cut-angles are used.

In a region surrounded by an ellipse J in FIG. 19, the spurious emission is as large as about 1.0. As is clear from FIG. 19, when the fractional bandwidth exceeds about 0.17, that is, when the fractional bandwidth exceeds about 17%, a large spurious emission having a spurious level of about 1 or more appears in a pass band even when the parameters defining the fractional bandwidth are changed. That is, as in the resonance characteristics shown in FIG. 18, a large spurious emission indicated by the arrow B appears in the band. Therefore, the fractional bandwidth is preferably, for example, about 17% or less. In this case, the spurious emission can be reduced by adjusting the thickness of the piezoelectric layer 2, the dimensions of the electrodes 3 and 4, and the like.

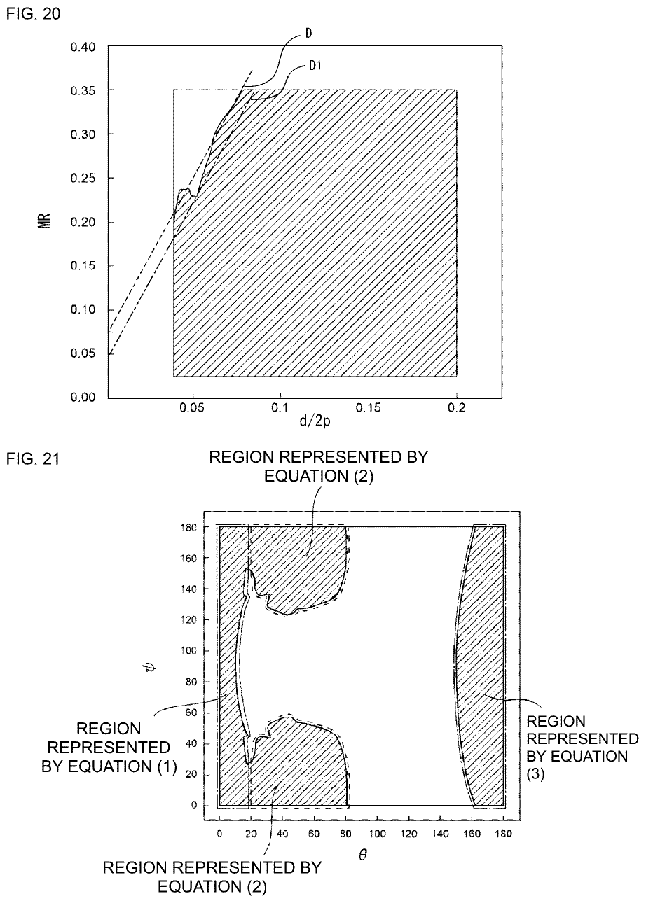

FIG. 20 is a graph showing a relationship between d/2p, the metallization ratio MR, and the fractional bandwidth. In the above acoustic wave device, various acoustic wave devices having different d/2p and different MR were configured, and the fractional bandwidths were measured. A hatched region on a right side of a broken line D in FIG. 20 is a region where the fractional bandwidth is about 17% or less. A boundary between the hatched region and an unhatched region is represented by MR=about 3.5(d/2p)+0.075. That is, MR=about 1.75(d/p)+0.075. Consequently, for example, MR preferably satisfies: MR≤about 1.75(d/p)+0.075. In this case, the fractional bandwidth is likely to be about 17% or less. A region on a right side of MR=about 3.5(d/2p)+0.05 indicated by an alternate long and short dash line D1 in FIG. 20 is more preferable. That is, when MR is about 1.75(d/p)+0.05 or less, the fractional bandwidth can be reliably set to about 17% or less.

FIG. 21 is a diagram showing a map of fractional bandwidths for Euler angles (0°, θ, ψ) of LiNbO₃ when d/p is brought as close to 0 as possible. Hatched regions in FIG. 21 are regions in which a fractional bandwidth of at least 5% or more can be obtained, and ranges of these regions can be approximated by Equation (1), Equation (2), and Equation (3) below.

Equation (1)

Equation (2)

(0°±10°, [180°−30° (1−(ψ−90)²/8100)^{1/2}] to 180°, any ψ) Equation (3)

Consequently, the Euler angles range of Equation (1), Equation (2), or Equation (3) above is preferable because the fractional bandwidth can be sufficiently widened. The same applies when the piezoelectric layer 2 is a lithium tantalate layer.

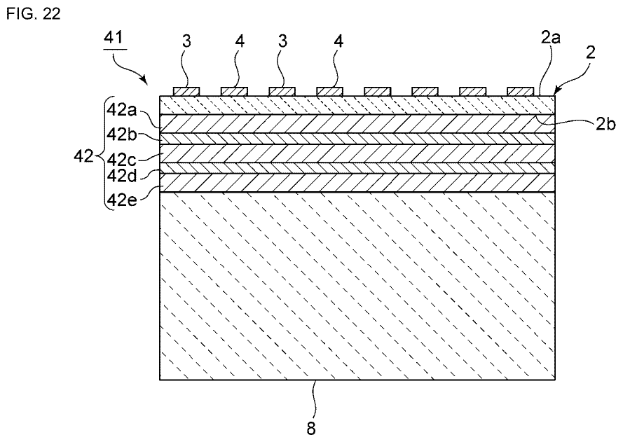

FIG. 22 is an elevational sectional view of an acoustic wave device including an acoustic multilayer film.

In an acoustic wave device 41, an acoustic multilayer film 42 is laminated on a second main surface 2b of a piezoelectric layer 2. The acoustic multilayer film 42 has a laminated structure including low acoustic impedance layers 42a, 42c, and 42e having relatively low acoustic impedance and high acoustic impedance layers 42b and 42d having relatively high acoustic impedance. When the acoustic multilayer film 42 is used, bulk waves in a thickness shear mode can be confined in the piezoelectric layer 2 without using the cavity 9 in the acoustic wave device 1. In the acoustic wave device 41 as well, for example, by setting d/p to about 0.5 or less, resonance characteristics based on the bulk waves in the thickness shear mode can be obtained. In the acoustic multilayer film 42, the numbers of laminated layers of the low acoustic impedance layers 42a, 42c, and 42e and the high acoustic impedance layers 42b and 42d are not particularly limited. At least one of the high acoustic impedance layers 42b and 42d only needs to be located farther from the piezoelectric layer 2 than the low acoustic impedance layers 42a, 42c, and 42e.

The low acoustic impedance layers 42a, 42c, and 42e and the high acoustic impedance layers 42b and 42d can be made of appropriate materials as long as the above relationship regarding the acoustic impedance is satisfied. Examples of the material of the low acoustic impedance layers 42a, 42c, and 42e include silicon oxide or silicon oxynitride. Examples of the material of the high acoustic impedance layers 42b and 42d include alumina, silicon nitride, or metals.

In the piezoelectric bulk wave device according to the first preferred embodiment, the acoustic multilayer film 42 illustrated in FIG. 22 may be provided between, for example, the silicon substrate and the piezoelectric layer.

In the piezoelectric bulk wave device 10 according to the first preferred embodiment including the acoustic wave resonators that use the bulk waves in the thickness shear mode, d/p is preferably, for example, about 0.5 or less, and more preferably about 0.24 or less, as described above. Thus, even better resonance characteristics can be obtained. Furthermore, in the piezoelectric bulk wave device 10 according to the first preferred embodiment including the acoustic wave resonators that use the bulk waves in the thickness shear mode, as described above, MR preferably, for example satisfies: MR≤about 1.75(d/p)+0.075. In this case, spurious emission can be reduced or prevented more reliably.

In the piezoelectric bulk wave device 10 according to the first preferred embodiment including the acoustic wave resonators that use the bulk waves in the thickness shear mode, the functional electrode may be a functional electrode including a pair of the electrode 3 and the electrode 4 illustrated in FIG. 17.

The piezoelectric layer 14 in the piezoelectric bulk wave device 10 according to the first preferred embodiment including the acoustic wave resonators that use the bulk waves in the thickness shear mode is preferably, for example, a lithium niobate layer or a lithium tantalate layer. Preferably, the Euler angles (φ, θ, ψ) of lithium niobate or lithium tantalate constituting the piezoelectric layer 14 are in the range of Equation (1), Equation (2), or Equation (3) above. In this case, the fractional bandwidth can be sufficiently widened.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric bulk wave device comprising:
a piezoelectric substrate including a support including a silicon substrate and a piezoelectric layer on the support;
a first wire electrode and a second wire electrode on the piezoelectric substrate; and
a functional electrode on the piezoelectric layer, connected to at least one of the first wire electrode and the second wire electrode, and including a plurality of electrodes; wherein
at least two of the first wire electrode, the second wire electrode, and the plurality of electrodes of the functional electrode include a first electrode film and a second electrode film connected to different potentials; and
a plane orientation of the silicon substrate is (111), and ψ in Euler angles (φ, θ, ψ) of the silicon substrate is an angle within a range of about 10°+120°×n≤ψ≤about 50°+120°×n or about 70°+120°×n≤ψ≤about 110°+120°×n, where n is any integer.

2. The piezoelectric bulk wave device according to claim 1, wherein the first electrode film is the first wire electrode, and the second electrode film is the second wire electrode.

3. The piezoelectric bulk wave device according to claim 1, wherein the piezoelectric layer is a lithium tantalate layer or a lithium niobate layer.

4. The piezoelectric bulk wave device according to claim 3, wherein a bulk wave in a thickness shear mode is generated.

5. The piezoelectric bulk wave device according to claim 3, wherein
the plurality of electrodes of the functional electrode are at least one pair of electrodes on a same main surface of the piezoelectric layer;
the support includes an acoustic reflector that overlaps at least a portion of the functional electrode in plan view; and
d/p is about 0.5 or less, where d is a thickness of the piezoelectric layer and p is a center-to-center distance between the multiple electrodes adjacent to each other.

6. The piezoelectric bulk wave device according to claim 5, wherein d/p is about 0.24 or less.

7. The piezoelectric bulk wave device according to claim 5, wherein the acoustic reflector is a cavity.

8. The piezoelectric bulk wave device according to claim 4, wherein
the plurality of electrodes of the functional electrode are at least one pair of electrodes on a same main surface of the piezoelectric layer; and
when viewed from a direction in which the plurality of electrodes adjacent to each other face each other, a region where the multiple electrodes adjacent to each other overlap is an excitation region, and MR≤about 1.75(d/p)+0.075, where MR is a metallization ratio of the multiple electrode to the excitation region.

9. The piezoelectric bulk wave device according to claim 4, wherein Euler angles (φ, θ, ψ) of the lithium niobate layer or the lithium tantalate layer as the piezoelectric layer are in a range of Equation (1), Equation (2), or Equation (3) below:
(0°±10°, 0° to 20°, any ψ) Equation (1);
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Equation (2); and
(0°±10°, [180°−30° (1−(ψ−90)²/8100)^{1/2}] to 180°, any ψ) Equation (3).

10. The piezoelectric bulk wave device according to claim 1, wherein the support includes an insulating layer on the silicon substrate.

11. The piezoelectric bulk wave device according to claim 10, wherein the insulating layer includes silicon oxide or tantalum pentoxide.

12. The piezoelectric bulk wave device according to claim 10, wherein the insulating layer includes at least one recess, and the piezoelectric layer closes the at least one recess to define at least one cavity.

13. The piezoelectric bulk wave device according to claim 10, wherein the insulating layer includes a plurality of recesses, and the piezoelectric layer closes the plurality of recesses to define a plurality of cavities.

14. The piezoelectric bulk wave device according to claim 12, wherein the at least one cavity is provided only in the insulating layer.

15. The piezoelectric bulk wave device according to claim 12, wherein the at least one cavity is provided in the insulating layer and the silicon substrate.

16. The piezoelectric bulk wave device according to claim 13, wherein the plurality of cavities are provided only in the insulating layer.

17. The piezoelectric bulk wave device according to claim 13, wherein the plurality of cavities are provided in the insulating layer and the silicon substrate.

18. The piezoelectric bulk wave device according to claim 1, wherein the piezoelectric layer includes at least one of lithium niobate, lithium tantalate, zinc oxide, aluminum nitride, quartz crystal, or lead zirconate titanate.

19. The piezoelectric bulk wave device according to claim 1, wherein the piezoelectric layer is directly on the silicon substrate.
